(19) United States
(12) Patent Application Publication
(10) Pub. No.: US 2007/0182279 A1
(43) Pub. Date: Aug. 9, 2007

(54) Surface acoustic wave device and electronic apparatus

(75) Inventors: Shuichi Kawano, Shiojiri (JP); Satoshi Fujii, Sanda (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/700,570

(22) Filed: Jan. 31, 2007

(30) Foreign Application Priority Data
Feb. 8, 2006 (JP) 2006-031319
Nov. 13, 2006 (JP) 2006-306318

(51) Int. Cl. H03H 9/25

(52) U.S. Cl. 310/313 R

(57) ABSTRACT

A surface acoustic wave device includes: (a) a substrate; (b) a piezoelectric film formed on top of the substrate; (c) an electrode for generating a surface acoustic wave formed on top of the piezoelectric film; (d) a first covering film formed on the electrode to cover the electrode, and made of the same material as that of the piezoelectric film; and (e) a second covering film formed on the first covering film.

### CROSS-REFERENCES TO RELATED APPLICATIONS

The entire disclosure of Japanese Patent Application No. 2006-306318, filed on Nov. 13, 2006 and Japanese Patent Application No. 2006-31319, filed on Feb. 8, 2006 is expressly incorporated herein by reference.

### BACKGROUND

1. Technical Field

The present invention relates to a device utilizing a surface acoustic wave (SAW).

2. Related Art

A surface acoustic wave device (SAW filter) is an electro-mechanical conversion device that utilizes a surface wave traveling along the surface of a piezoelectric material, and it includes, as its basic configuration, a piezoelectric material and a pair of comb-toothed electrodes (IDTs: interdigital transducers) formed on top of the piezoelectric material. When an electric signal is applied to one of the comb-toothed electrodes, the piezoelectric material distorts, causing a surface acoustic wave to travel, and then the electric signal is output from the other comb-toothed electrode. In the above process, a particular frequency is selected, so surface acoustic wave devices can be used as resonators, filters, or similar.

Such devices have been used in communication apparatuses (wireless and wired apparatuses), sensors, touch panels, and other various fields, and in particular, they are essential in the field of mobile communication, as represented by cellular phones. They are also used in system apparatuses in broadcasting stations, mobile phone base stations, etc., and high-performance devices (elements) are installed in those systems (e.g. antenna units).

For example, with higher frequency waves being used in optical communication and in mobile communication, many studies have been conducted for various types of material for surface acoustic wave devices. As explained in detail later, examples of a way to enable a surface acoustic wave device to generate higher frequencies include: (1) shortening the distance between each tooth in the comb-toothed electrode; and (2) increasing a surface acoustic wave's propagation speed. In the above two, there is a limit to shortening the distance between each tooth in a comb-toothed electrode due to microfabrication technique limitations. Accordingly, much importance has been placed on techniques to increase surface acoustic wave propagation speed.

For instance, devices using sapphire or diamond have been studied. In particular, attention has been paid to techniques to improve the above propagation speed by layering diamond and a piezoelectric material.

For example, JP-A-6-232677 discloses art relating to a surface acoustic wave device that employs a layered configuration including a layer of diamond or similar, a layer of a metal oxide, and a layer of a piezoelectric substance.

Also, JP-A-9-098059 discloses art relating to a surface acoustic wave device employing a layered configuration including a diamond layer, a ZnO layer and a SiO₂ layer, that has excellent high-frequency band performance.

The present inventors are engaged in research and development of various types of electronic apparatuses provided with surface acoustic wave devices, and are studying a device structure that can achieve much higher performance.

More specifically, the present inventors are studying a device structure that achieves (1) faster propagation speed, (2) larger electromechanical coupling coefficient, (3) smaller temperature-induced frequency change, and (4) greater electric resistance.

However, JP-A-6-232677 above, for instance, has a problem in that, because it employs a configuration where comb-shaped electrodes are covered with a thin SiO₂ film as shown in FIG. 2, etc., of the reference, the internal stress from the film is easily applied to the electrodes, and the electrodes break easily. Furthermore, the above configuration decreases heat radiation, causing a problem of electrode deterioration due to thermal stress.

JP-A-9-098059 above also employs a configuration where comb-toothed electrodes are covered with a ZnO layer, and so has the same problems of internal stress from ZnO, and heat radiation. Furthermore, there is the problem of crystallinity in ZnO on the comb-toothed metallic electrodes.

The electrode deterioration described above leads to low electric resistance, resulting in deterioration of surface acoustic wave device properties.

### SUMMARY

An advantage of some aspects of the invention is the improvement of the properties of a surface acoustic wave device, and, in particular, the reduction of electrode deterioration in the device. Another advantage is the reduction of electrode deterioration and the improvement of electric resistance, and at the same time, the improvement of propagation speed and the achievement a larger electromechanical coupling coefficient or a reduced temperature-induced frequency change.

According to a first aspect of the invention, provided is a surface acoustic wave device including: (a) a substrate; (b) a piezoelectric film formed on top of the substrate; (c) an electrode for generating a surface acoustic wave formed on top of the piezoelectric film; (d) a first covering film formed on the electrode to cover the electrode, and made of the same material as that of the piezoelectric film; and (e) a second covering film formed on the first covering film.

Since a covering film of the same material as that of the piezoelectric film is formed on the electrode to cover the electrode, the electrode is wholly enclosed within the piezoelectric film, improving the electrode in terms of stress-migration (stress-migration resistance). As a result, it is possible to reduce electrode deterioration and improve electric resistance, resulting in improved surface acoustic wave device properties.

The piezoelectric film and the first covering film are preferably made of any of zinc oxide, lithium tantalate, lithium niobate, and aluminum nitride.

Preferably, the substrate has a hard layer on its surface, and the piezoelectric film is formed on the hard layer. Using the above hard layer, it is possible to reduce electrode deterioration and improve electric resistance, and at the same time, to improve propagation speed and achieve a larger electromechanical coupling coefficient or a reduced temperature-induced frequency change.

The hard layer is preferably made of any of diamond, boron nitride and sapphire.

The product kh of the thickness h of the covering film and the wavenumber k of a surface acoustic wave on the surface acoustic wave device is preferably greater than or equal to 0.003 and less than or equal to 0.2. Setting the covering film thickness to achieve a value within the above range, it is possible to reduce electrode deterioration and improve electric resistance, and at the same time, to improve propagation speed and achieve a larger electromechanical coupling coefficient or a reduced temperature-induced frequency change.

Preferably, the substrate has a polycrystalline hard layer, and the piezoelectric film is a polycrystalline film formed on the polycrystalline hard layer. With the above configuration, it is possible to improve electric resistance even if the piezoelectric film is a polycrystalline film.

According to a second aspect of the invention, provided is a surface acoustic wave device including: (a) a substrate with a hard layer; (b) a piezoelectric film formed on the hard layer; (c) an electrode for generating a surface acoustic wave formed on top of the piezoelectric film; (d) a first covering film formed on the electrode to cover the electrode, and having a thermal conductivity greater than that of amorphous SiO₂; and (e) a second covering film formed on the first covering film.

By forming the first covering film having a thermal conductivity greater than that of amorphous SiO₂ on the electrode to cover the electrode, as above, it is possible to improve heat radiation, resulting in improved surface acoustic wave device properties.

The piezoelectric film is preferably made of any of zinc oxide, lithium tantalate, lithium niobate, and aluminum nitride.

The first covering film preferably has a thermal conductivity of 10 W/mK or greater.

The first covering film is preferably zinc oxide or aluminum nitride.

According to a third aspect of the invention, provided is an electronic apparatus that has the above-described surface acoustic wave device. Here, “electronic apparatus” means apparatuses in general that realize a specific function via an electronic circuit or similar, and there is no limitation on configuration. Examples include a cellular phone, a personal computer, a PDA (personal digital assistant), an electronic databook/organizer, and other various apparatuses.

### BRIEF DESCRIPTION OF THE DRAWINGS

FIGS. 1A-1C are sectional views showing the steps in a method for manufacturing a surface acoustic wave device according to embodiment 1.

FIGS. 2A and 2B are sectional views showing the steps in a method for manufacturing a surface acoustic wave device according to embodiment 1.

FIG. 3 is a plan view illustrating a pattern example of comb-toothed electrodes 15a according to embodiment 1.

FIG. 4 is a diagram illustrating an example where the invention is applied in a cellular phone.

FIGS. 5A and 5B are diagrams illustrating an example where the invention is applied in a communication system.

FIG. 6 is a chart showing a KH value for the SiO₂, a KH value for the ZnO above the IDTs, and the ratio between the two.

FIG. 7 is a graph showing the phase velocity for each device (Types 1(a)-1(d) and Types 2(a)-2(d)).

FIG. 8 is a graph showing the frequency-temperature coefficient (TCF) for each device.

FIG. 9 shows a formula indicating the frequency-temperature characteristics of a device.

FIG. 10 is a chart showing the (S21) characteristic of a two-port resonator based on Type 2(c).

FIG. 11 is a diagram showing a circuit for evaluating S21.

FIG. 12 is a chart showing the relationship of insertion loss (ΔIL [dB]) with time.

FIG. 13 is a chart showing a KH value for the SiO₂ and a KH value for the ZnO above the IDTs in Types 1(a)-1(f).

FIG. 14 is a graph showing the phase velocity for each device (Types 1(a)-1(f).

FIGS. 15A-15C are sectional views showing the steps in a method for manufacturing a surface acoustic wave device according to embodiment 3.

FIGS. 16A and 16B are sectional views showing the steps in a method for manufacturing a surface acoustic wave device according to embodiment 3.

FIG. 17 is a chart showing the thermal conductivity for each material.

### DESCRIPTION OF EXEMPLARY EMBODIMENTS

Next, embodiments of the invention will be explained in detail with reference to the attached drawings. Note that the same or related reference numerals are used for portions having the same function, so repeated explanation of those will be omitted.

### Embodiment 1

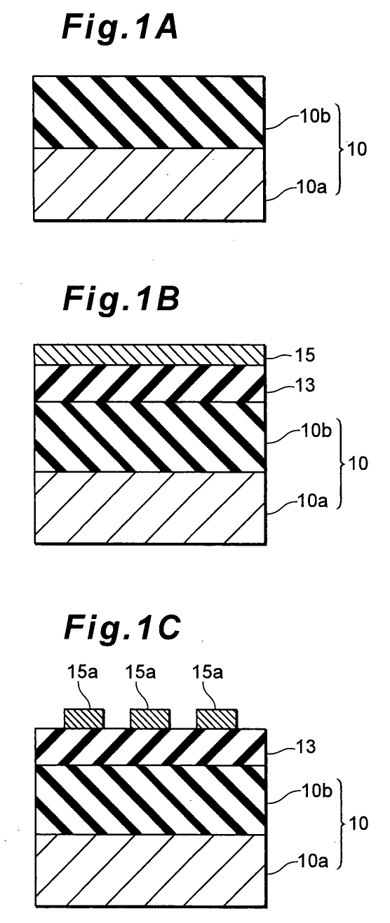

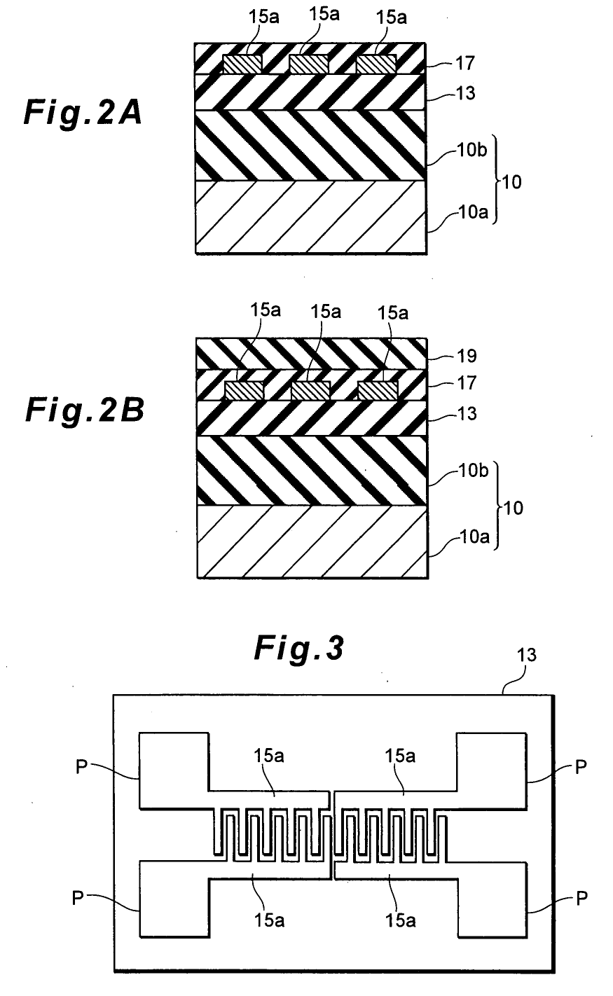

FIGS. 1 and 2 are sectional views showing the steps in a method for manufacturing a surface acoustic wave device according to this embodiment.

First, the configuration of a surface acoustic wave device according to this embodiment will be described. As shown in FIG. 2B, which illustrates the last step of the manufacturing method, the surface acoustic wave device according to this embodiment includes a substrate 10, a piezoelectric film 13, comb-toothed electrodes 15a, an electrode covering film 17, and a protection film 19.

The substrate 10 supports each component, and in this embodiment, a diamond substrate is used. The diamond substrate mentioned here is a substrate obtained by forming a diamond layer 10b on a silicon layer (silicon substrate) 10a.

Using the above substrate 10 with a hard layer (hard film) of diamond or similar on its surface, the propagation speed of a surface acoustic wave can be increased, and it becomes possible to generate higher frequencies. Also, using the above hard layer, a larger electromechanical coupling coefficient can be obtained. Instead of diamond, boron nitride or sapphire may also be used for the hard layer. In particular, diamond has great hardness, so it is ideally used for the surface acoustic wave device.

The piezoelectric film (piezoelectric substance or piezoelectric material) 13 is formed on one surface (on the diamond layer 10b) of the substrate 10, and its constituent material is, for example, zinc oxide (ZnO). Instead of zinc oxide, any material may be used for the piezoelectric film 13, as long as it is a constituent material having piezoelectricity; and examples of those materials include: lithium tantalate (LiTaO₃), lithium niobate (LiNbO₃), and aluminum nitride (AlN).

The comb-toothed electrodes 15a are formed on the piezoelectric film 13, forming a planar pattern of paired comb teeth (see FIG. 3), and are made of a conductive material, e.g. aluminum (Al). The paired comb-toothed electrodes 15a are electrodes for generating a surface acoustic wave (electrodes for exciting a surface acoustic wave, or electrodes for performing electromechanical conversion), and when an electric signal is applied to one comb-toothed electrode, the piezoelectric film 13 distorts, causing a surface acoustic wave to propagate, and the electric signal is obtained from the other comb-toothed electrode 15a. In the above process, a particular frequency is selected. The frequency band (frequency characteristic) in each surface acoustic wave device has a pass-band characteristic that centers on a frequency (f) calculated by v/d (f=v/d: d is the distance between each tooth of one comb-toothed electrode 15a, and v is the propagation speed of the surface acoustic wave). So, using a hard layer, such as the above-mentioned diamond layer, the propagation speed (v) increases, and consequently, a device capable of generating higher frequencies can be obtained.

The electrode covering film (electrode covering layer, covering film, first protection film, or insulating layer) 17 is made of the same material as the constituent material of the piezoelectric film 13, and formed on the comb-toothed electrodes 15a so that the film 17 covers the overall comb-toothed electrodes 15a. In other words, the film 17 is formed on the exposed portions of the piezoelectric film 13, and on the comb-toothed electrodes 15a.

As described above, according to this embodiment, the comb-toothed electrodes 15a are covered with the same material (the electrode covering film 17) as the constituent material of the piezoelectric film 13, so the comb-toothed electrodes 15a are wholly enclosed with the piezoelectric films (13 and 17). Accordingly, the comb-toothed electrodes 15a can be improved in terms of resistance to stress-migration.

If, for example, the electrode covering film 17 is formed of a material different from that of the piezoelectric film 13, stress is applied to the comb-toothed electrodes 15a due to the difference between these films in internal stress or in thermal expansion coefficient, which constitutes one reason for electrode destruction.

On the other hand, in this embodiment, by enclosing the comb-toothed electrodes 15a with the piezoelectric films (13 and 17), the comb-toothed electrodes 15a can be improved in terms of resistance to stress-migration.

In addition, if using zinc oxide or aluminum nitride for the electrode covering film 17, electrostatic breakdown can be reduced by the semiconductive properties of those materials.

Note that the “same material as the constituent material of the piezoelectric film 13” mentioned above means that the two materials have the same main composition, and does not mean that the two materials are completely the same as regards other various characteristics, which may vary according to, for example, the conditions of film-formation (reaction temperature, the type and flow rate of reaction gas, etc.).

Also, as explained in detail later, the electrode covering film 17 is thinner than the piezoelectric film 13—for example, while the piezoelectric film 13 is approximately 525 nm, the electrode covering film 17 is approximately 50 nm, i.e., the electrode covering film 17 has a thickness of 1/10 or less of the thickness of the piezoelectric film 13. Also, the product (hk) of the thickness (h) of the electrode covering film 17 and the wavenumber (k; the inverse number of the frequency) of a surface acoustic wave is preferably within the range of greater than or equal to 0.003 and less than or equal to 0.2.

The protection film (second protection film, or insulating layer) 19 is formed on the electrode covering film 17, and is made of an insulating material such as silicon oxide (SiO₂). This protection film 19 functions to protect the piezoelectric film 13 and the comb-toothed electrodes 15a from the ambient environment. The piezoelectric film 13 and the comb-toothed electrodes 15a are covered with the electrode covering film 17, and this film 17 also functions as a protection film, but the thickness of the film 17 is small. So the protection film 19 also functions to supplement the protective ability of the film 17. Instead of silicon oxide, alumina (aluminum oxide or AlO₃) or gallium phosphate (GaPO₃) may also be used for the protection film 19.

As explained above, the surface acoustic wave device according to this embodiment has a layered configuration composed of, from top down, the protection film (SiO₂) 19, the electrode covering film (ZnO) 17, the comb-toothed electrodes 15a, the piezoelectric film (ZnO) 13, and the diamond layer 10b.

Although not shown in FIG. 2B, each comb-toothed electrode 15a is coupled with an electrode pad P, and formed as one continuous pattern, for example, as shown in FIG. 3. The electrode covering film 17 and the protection film 19 formed on this electrode pad P are removed so that the electrode pad P is exposed. The electrode pad P is bonded to an external terminal via a wire or similar (wire bonding), realizing electrical coupling of the surface acoustic wave device with an external device.

Next, the steps in a method for manufacturing the surface acoustic wave device according to this embodiment will be explained.

As shown in FIG. 1A, a diamond substrate having a diamond layer 10b on its main surface is prepared as a substrate 10. For example, a substrate 10 in which a polycrystalline diamond layer 10b of around 20 μm (average thickness) is formed on a silicon layer 10a of around 1000 μm (average thickness) is used.

Then, as shown in FIG. 1B, a piezoelectric film 13—for example, a zinc oxide film—is deposited (coated) on the diamond layer 10b, using a film formation method such as an RF (radio frequency) spattering method (hereinafter simply referred to as a spattering method), so that the piezoelectric film 13 has a thickness of around 525 nm (average thickness). As for the conditions for film formation, film formation is performed, for example, with a power of 1.0 kW, a film-formation temperature of 500° C. and a gas pressure (ambient pressure) of 0.5 Pa using sintered zinc oxide as a target material, and also using argon (Ar) with a flow rate of 50 sccm and oxygen (O₂) with a flow rate of 50 sccm, as reaction gas.

Next, a conductive film 15, e.g. an Al (aluminum) film is deposited to have a thickness of around 42 nm (average thickness), using a film-formation method such as a DC (direct current) spattering method. Film formation is performed, for example, with a power of 1.0 kW, a film-formation temperature of 25° C. (room temperature), and a gas pressure (ambient pressure) of 1.0 Pa, using Al as a target material, and also using Ar with a flow rate of 50 sccm as atmosphere gas.

Then, as shown in FIG. 1C, comb-toothed electrodes 15a are formed by patterning the conductive film 15. An example of the patterning method is: applying a photoresist film (not shown in the drawing) onto the conductive film 15; then conducting exposure and development (photolithography) to form a photoresist film (hereinafter simply referred to as a resist film) with a comb-toothed pattern; etching using the above-formed resist film as a mask to remove the conductive film 15 not covered with the resist film; and thereby forming the comb-toothed electrodes 15a. Etching is performed, for example, via RIE (reactive ion etching), using, for example, gas mainly containing boron chloride (BCl₃) and chlorine (Cl₂) as reactive gas. After etching, the remaining resist film is removed.

Then, as shown in FIG. 2A, a film (layer) of the same material as that of the piezoelectric film 13 is formed on the exposed portion of the piezoelectric film 13 and on the comb-toothed electrodes 15a, as an electrode covering film 17. In this embodiment, a zinc oxide film is deposited to have a thickness of around 50 nm (average thickness) on the piezoelectric film 13. An example of the film-formation method used is an RF spattering method, and film-formation is performed, for example, with a power of 1.0 kW, a film-formation temperature of 250° C., and a gas pressure (ambient pressure) of 0.5 Pa, using sintered zinc oxide as a target material, and also using Ar with a flow rate of 50 sccm and O₂ with a flow rate of 50 sccm, as reaction gas.

The electrode covering film 17 is formed on the exposed portion of the piezoelectric film 13, and on the comb-toothed electrodes 15a, i.e., it is formed on different films. Thus, the development (orientation) of the electrode covering film 17 is reduced, compared to the lower piezoelectric film 13. However, the thickness of the electrode covering film 17 is small, so not so much influence is given to piezoelectricity.

Next, as shown in FIG. 2B, a protection film (second protection film or insulating layer) 19, for example, a silicon oxide film is deposited on the electrode covering film 17 to have a thickness of around 420 nm (average thickness), using a film-formation method, such as an RF spattering method. Film formation is performed, for example, with a power of 1.0 kW, a film-formation temperature of 200° C., and a gas pressure (ambient pressure) of 0.5 Pa, using sintered silicon oxide as a target material, also using Ar with a flow rate of 50 sccm and O₂ with a flow rate of 50 sccm, as reaction gas.

As a result of the steps above, the surface acoustic wave device is almost completed.

FIG. 3 is a plan view illustrating a pattern example of comb-toothed electrodes 15a according to this embodiment. The reference P indicates an electrode pad. However, the pattern is not limited to the one shown in FIG. 3. For example, the number of comb teeth in each electrode may be changed, or shapes other than the comb-toothed shape may also be employed. Also, the location of each electrode, or the number of electrodes may be changed too.

The characteristics of the surface acoustic wave device formed via the above explained steps were examined using a vector network analyzer (HP8753c). More specifically, an S parameter was measured using the above analyzer, and insertion loss was evaluated from the results of the measurement.

In the above examination, in order to obtain an output power of 30 dBm or greater from the surface acoustic wave device, a high-frequency amplifier was attached, and the input power was adjusted to be able to respond to the above output power. Then, high-frequency pulses were applied to the input-side comb-toothed electrode of the surface acoustic wave device to excite a surface acoustic wave, and the signal (S21) output from the output-side comb-toothed electrode was measured to calculate the above-described insertion loss. Here, S21 is a parameter (S-parameter) that indicates the electricity transmission characteristic, i.e., the power transmission characteristic of a device, that is shown by the logarithm of the ratio of transmitted wave power to input wave power. The larger the S-parameter S21 is, the better the device is, causing less power loss. Insertion loss can be obtained by making the above S21 value a positive value.

In the evaluation of insertion loss, a favorable result was obtained: the surface acoustic wave device according to this embodiment showed an insertion loss of about 6 dB.

The above-explained insertion loss increases due to destruction or loss of the comb-toothed electrodes. However, as stated above, the surface acoustic wave device according to this embodiment achieves improved resistance to stress-migration and improved electrostatic resistance, which seems to reduce the destruction or loss of the comb-toothed electrodes, and result in decreased insertion loss.

Also, because the surface acoustic wave device according to this embodiment achieves improved resistance to stress-migration and improved electrostatic resistance, it has improved electric-resistance, being capable of enduring a power of 300 mW or over.

Furthermore, in the surface acoustic wave device according to this embodiment, the electrode covering film (film made of the same material as that of the piezoelectric film 13) 17 is formed thinner than the piezoelectric film 13 (for example, in the above-described example, the piezoelectric film 13 is around 525 nm, while the electrode covering film 17 is around 50 nm, one tenth or less of the thickness of the piezoelectric film 13), and accordingly, the surface acoustic wave device has the same surface acoustic wave propagation speed, the same electromechanical coupling coefficient, and the same frequency-temperature characteristics, as in a surface acoustic wave device where no electrode covering film 17 is formed.

In particular, as a result of their study, the present inventors have found that, where the product (hk) of the thickness h [Å (angstrom)=10⁻⁸ cm] of the electrode covering film 17 and the wavenumber k=2π/λ[m⁻¹] of a surface acoustic wave is within the range of greater than or equal to 0.003 and less than or equal to 0.2, the surface acoustic wave device has the same surface acoustic wave propagation speed, the same electromechanical coupling coefficient, and the same frequency-temperature characteristics, as in a surface acoustic wave device where no electrode covering film 17 is formed.

Moreover, as already explained before, since the surface acoustic wave device according to this embodiment achieves improved resistance to stress-migration and improved electrostatic resistance, it has more improved electric resistance than a surface acoustic wave device where no electrode covering film 17 is formed, or where an electrode covering film 17 is formed of a material different from that of the piezoelectric film 13.

### Embodiment 2

In embodiment 2, the characteristics of a SAW resonator with the SiO₂/ZnO/diamond configuration explained in detail in embodiment 1 will be specifically explained. As explained before, the above SAW resonator has excellent stability with temperature at GHz frequencies. Using that SAW resonator, it is possible to realize a 2-3 GHz oscillator with low phase noise.

According to Lesson's Model, phase noise can be lessened by increasing electric power in an oscillating loop. In other words, in order to decrease phase noise, it is necessary to prepare a SAW resonator configuration that can endure an electricity increase.

The present inventors have found that electric resistance can be improved by placing ZnO above and below the IDTs, so that finding will be explained in detail below.

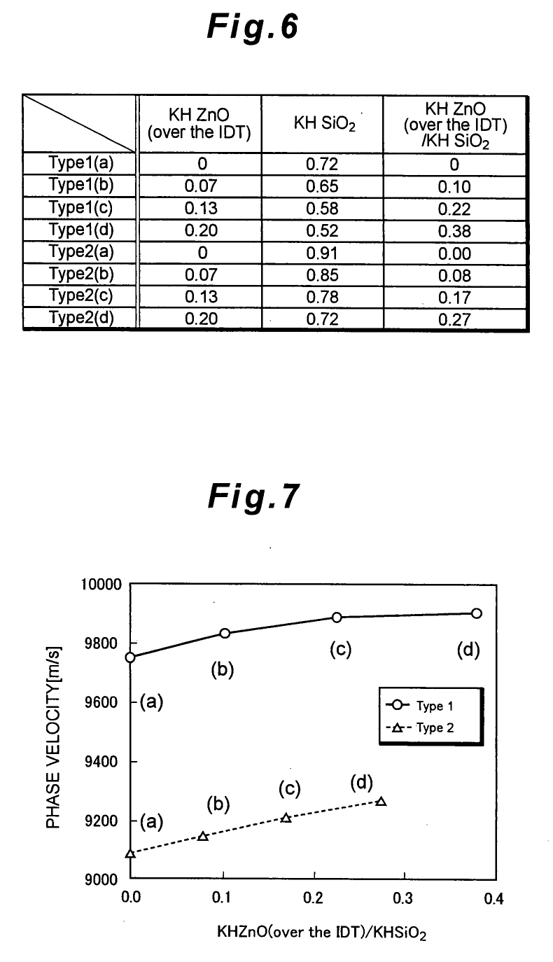

The following study was conducted to obtain a device that keeps a high phase velocity of 9000 m/s or larger and has a frequency-temperature characteristic with a peak temperature of 25° C. First, the KH value for the SiO₂ (KH SiO₂) and the KH value for the ZnO above the IDTs (KH ZnO (above the IDTs)) were changed as shown in FIG. 6. The KH value is calculated by the formula: KH=2 πH/λ, wherein H and λ represent the film thickness and the wavelength, respectively. Here, K and H both are capitalized. FIG. 6 is a chart showing the KH value for the SiO₂, the KH value for the ZnO above the IDTs, and the ratio between the two. The study was conducted on two types of configuration—Type 1, where the KH value for the total thickness of SiO₂ and ZnO above the IDTs was 0.72, and Type 2, where the KH value for that total thickness was 0.92—changing the KH ratio between SiO₂ and ZnO above the IDTs in each type. The KH value for the ZnO below the IDTs was set to be 0.82.

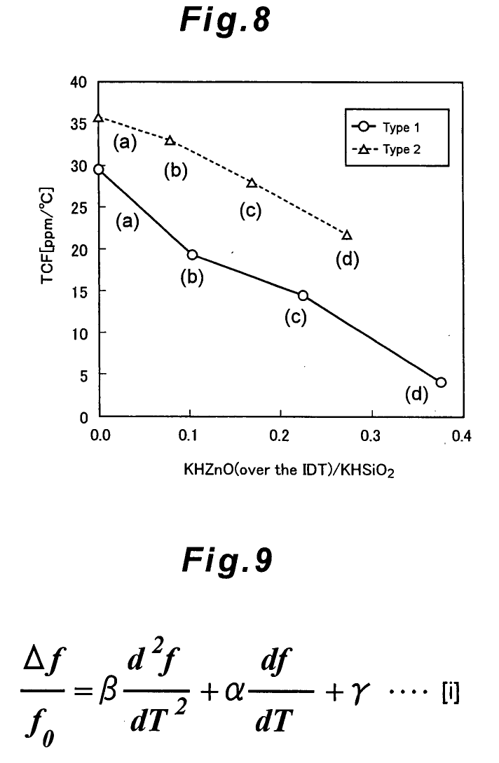

Then, the phase velocity and the primary TCF (Frequency-Temperature Coefficient: ppm/° C.) for each of the above devices were calculated via an FEM (see FIGS. 7 and 8). FEM stands for a Finite Element Method.

FIG. 7 is a graph showing the phase velocity (m/s) for each device (Types 1(a)-1(d) and Types 2(a)-2(d)). As shown in FIG. 7, the phase velocity showed an increasing trend, with the increase in ZnO above the IDTs. Also, Types 1(b)-1(d) and Types 2(b)-2(d) were found to have a high phase velocity of 9000 m/s or larger.

FIG. 8 is a graph showing the frequency-temperature coefficient (TCF) for each device. The peak temperature in the frequency-temperature characteristic of each device can be obtained from this graph.

Note that the frequency-temperature characteristic of each device is indicated by the formula [i] (approximate curve) shown in FIG. 9. In this formula, Δf indicates a variation in frequency, f0 indicates the center frequency, and T indicates a temperature. Coefficient β of the member where frequency f is differentiated twice with respect to temperature T is called a secondary TCF, and coefficient a of the member where frequency f is differentiated once with respect to temperature T is called a primary TCF.

Here, the secondary TCF for each film was not derived, and was difficult to accurately estimate, so the peak temperature for each device was approximately calculated from the actual measurement value of the secondary TCF for Type 1(a). More specifically, using the actual measurement value of the Type 1(a) secondary TCF (−0.02 ppm/° C.) and each device's primary TCF calculated via FEM, the peak temperature for each device was obtained. As a result, Type 2(c), with a primary TCF of 28.0 ppm/° C. was simulated as having a peak temperature of 25° C.

Accordingly, the Type 2(c) configuration can be regarded as a configuration that meets the currently intended phase velocity and temperature characteristics.

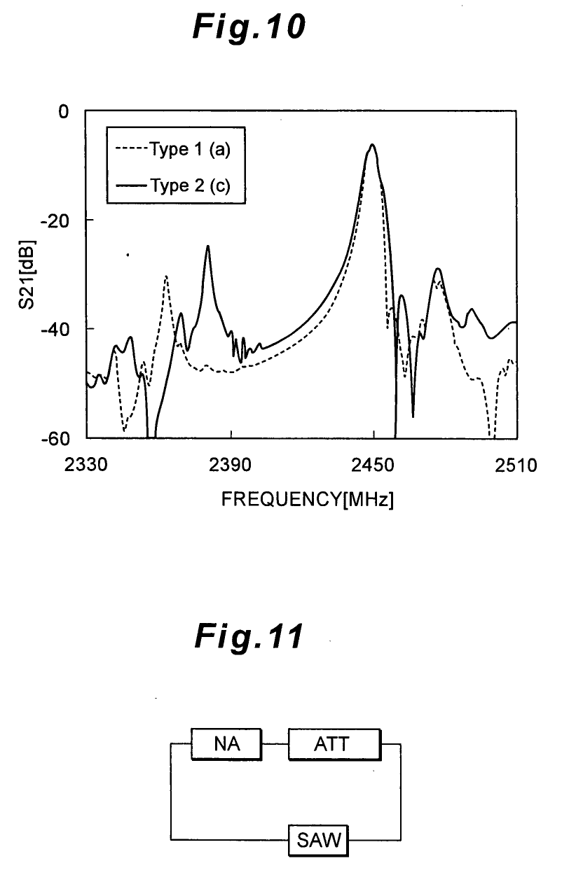

Next, a device having the Type 2(c) configuration was produced and assessed. FIG. 10 is a chart showing the (S21) characteristic of a two-port resonator based on Type 2(c). The vertical axis indicates S21 [dB], and the horizontal axis indicates frequency [MHz]. The S21 characteristic of Type 1(a) is also shown for comparison. The above Type 2(c) device showed a frequency of 2.45 GHz, an insertion loss of 6 dB, and a Q value of 495. As shown in FIG. 10, characteristics equal to those of Type 1(a) (comparative example) were obtained from Type 2(c). The Q value for Type 2(c) was a little bit smaller than that in the comparative example, because of the increase in electromechanical coupling coefficient. With respect to that point, the Q value can be increased by changing the design of the electrodes, e.g., increasing the number of comb teeth in the electrodes. Also, in the Type 2(c) device, the secondary TCF was −0.021 ppm/° C.², the primary TCF was 2.5 ppm/° C., and the peak temperature was 57° C. The before-explained simulation was performed using a material constant for a monocrystalline material. However, the actual device was a polycrystalline and thin film, so a certain gap was generated between the actual values and the above simulation. The S21 characteristic was measured using an evaluation circuit shown in FIG. 11. FIG. 11 is a diagram showing a circuit for evaluating S21. In FIG. 11, SAW, NA, and ATT indicate an evaluation target device, a vector network analyzer, and an attenuator, respectively. A high-frequency amplifier may also be connected between the NA and the SAW to change the input power.

Next, testing was conducted to evaluate the electric resistance for the device having the Type 2(c) configuration. In this testing, an input power of 25 dBm (300 mW) was applied via a signal of 2.45 GHz, which is the center frequency for the device (resonator), at room temperature, and then the frequency characteristic (insertion loss) was measured. For comparison, the same measurement was also conducted for Type 1(a).

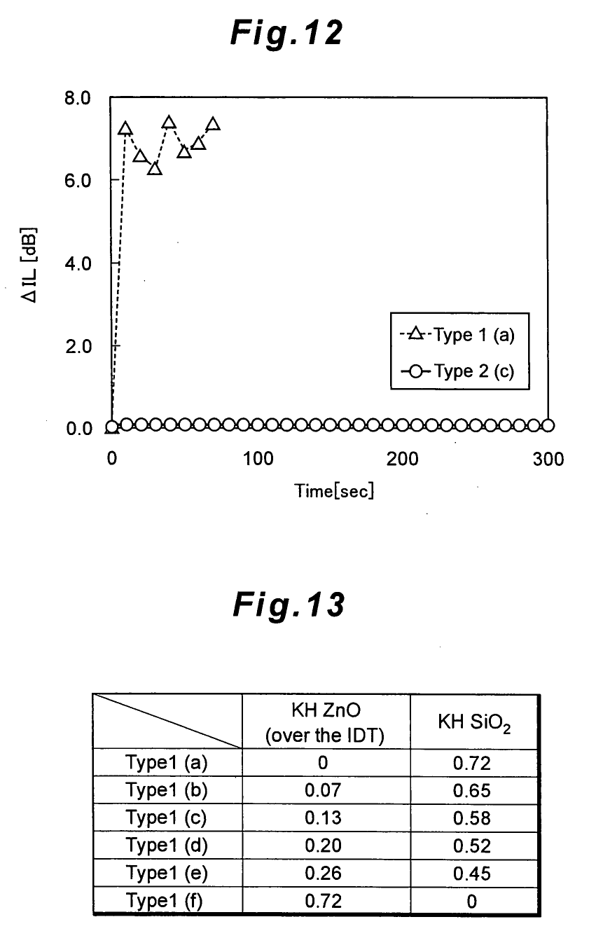

FIG. 12 shows the relationship of insertion loss (ΔIL [dB]) with time. As shown in FIG. 12, in Type 1(a), the insertion loss greatly increased immediately after the input power was applied. Meanwhile, in Type 2(c), the insertion loss did not change for 300 seconds after the input power was applied. Accordingly, the device with the Type 2(c) configuration was found to be able to endure a power of 25 dBm (300 mW), i.e., a considerable improvement in electric resistance was confirmed, relative to the device with the Type 1(a) configuration that is able to endure a power of around 10 dBm (10 mW).

One reason for the above improvement in electric resistance can be regarded as being the reduction of stress applied to the IDTs, as already explained in embodiment 1 previously. In other words, it is believed that the improvement has been achieved because the same material (ZnO) is placed above and below the IDTs, providing the same temperature characteristic in the layers above and below the IDTs, and because difference in stress is reduced between the layers above and below the IDTs. It is also believed that another reason is that ZnO, which is in contact with the IDTs, functions as a varistor, improving resistance to electrode destruction.

In this embodiment, the target peak temperature is set to be 25° C., so Type 2(c) has been specifically explained regarding Type 2(c)'s characteristics. However, the target peak temperature varies according to the purpose of use of the device, and it is a parameter that can be set in each case. Other devices (Types 1(b)-1(d), and Types 2(b) and 2(d)) also bring about the same advantageous effects, such as improvement in electric resistance. So, at least, the above advantageous effects can be brought about if the KH value for the ZnO above the IDTs is greater than or equal to 0.07 and less than or equal to 0.2 (see FIG. 6).

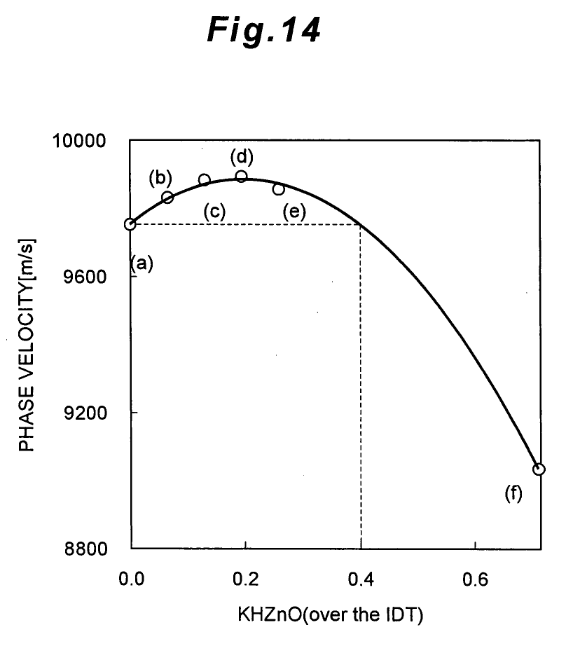

Regarding the phase velocity, the FEM calculation was also conducted for Types 1(e) and 1(f)shown in FIG. 13, in addition to Types 1(a)-1(d) above. FIG. 13 is a chart showing the KH values for the SiO₂ and for the ZnO above the IDTs, in Types 1(a)-1(f). The phase velocity for each device (Types 1(a)-1(f)) is shown in FIG. 14.

As shown in FIG. 14, Type 1(d) exhibits the highest phase velocity. The KH value for the ZnO above the IDTs (KH ZnO (above the IDTs)) where the phase velocity is almost the same as that in Type 1(a), which has no ZnO above the IDTs, is 0.4. Accordingly, a phase velocity equal to or greater than the phase velocity in Type 1(a) can be obtained if the KH value for the ZnO above the IDTs is less than or equal to 0.4. Also, if the phase velocity increases (i.e., the KH value for the ZnO above the IDTs increases), each comb tooth of the IDTs can be widened, bringing about the advantage of easy processing. So, it is also effective if the KH value for the ZnO above the IDTs is within the range of greater than 0, but less than or equal to 0.4.

Furthermore, the same material (ZnO) is placed above and below the IDTs in this embodiment, but it is also possible to place materials with a temperature characteristic of the same sign (±) above and below the IDTs. In other words, it is also possible to place, as an upper layer of the IDTs, a material having a temperature characteristic with the same sign (±) as that of the piezoelectric material placed as a lower layer of the IDTs. In this case too, difference in stress is reduced between the layers above and below the IDTs. Note that, obviously, the materials are ideally the same, as already explained before.

### Embodiment 3

While the IDT (device) characteristics are improved in terms of reduction of stress in embodiments 1 and 2, the device characteristics are improved by enhancing heat radiation in this embodiment. Note that the same reference numerals are used for the same portions as in embodiment 1, and so their detailed explanation is omitted.

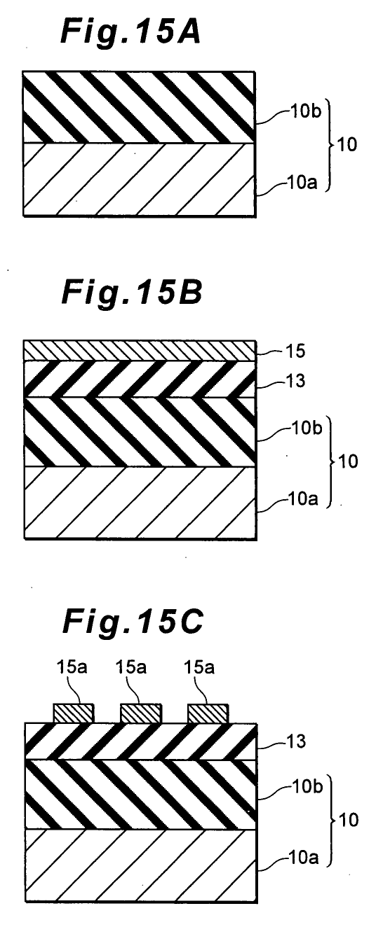

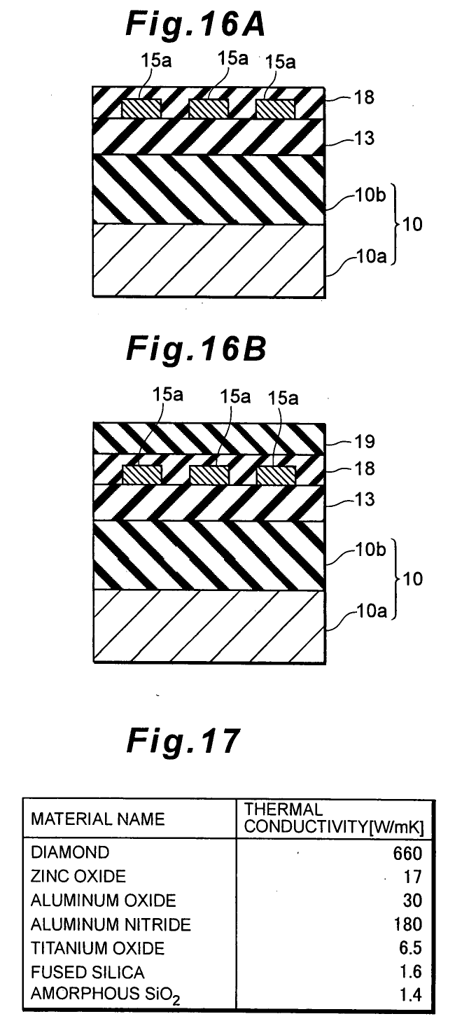

FIGS. 15 and 16 are sectional views showing the steps in a method for manufacturing a surface acoustic wave device according to this embodiment.

First, the configuration of a surface acoustic wave device according to this embodiment will be described. As shown in FIG. 16B, which illustrates the last step of the manufacturing method, the surface acoustic wave device according to this embodiment includes a substrate 10, a piezoelectric film 13, comb-toothed electrodes 15a, an electrode covering film 18, and a protection film 19.

The substrate 10 supports each component, and in this embodiment, a diamond substrate is used. The diamond substrate mentioned here is a substrate obtained by forming a diamond layer 10b on a silicon layer (silicon substrate) 10a.

Using the above substrate 10 with a hard layer (hard film) of diamond or similar on its surface, the propagation speed of a surface acoustic wave can be increased, and it becomes possible to generate higher frequencies. Also, using the above hard layer, a larger electromechanical coupling coefficient can be obtained. Instead of diamond, boron nitride or sapphire may also be used for the hard layer. In particular, diamond has great hardness, so it is ideally used for the surface acoustic wave device. Furthermore, a hard layer itself may also be used as the substrate, and crystal may be used too.

The piezoelectric film 13 is formed on one surface (on the diamond layer 10b) of the substrate 10, and its constituent material is, for example, zinc oxide (ZnO). Instead of zinc oxide, any material may be used for the piezoelectric film 13, as long as it is a constituent material having piezoelectricity; and examples of those materials include: lithium tantalate (LiTaO₃), lithium niobate (LiNbO₃), and aluminum nitride (AlN).

The comb-toothed electrodes 15a are formed on the piezoelectric film 13, forming a planar pattern of paired comb teeth (see FIG. 3), and are made of a conductive material, e.g. aluminum (Al). The paired comb-toothed electrodes 15a are electrodes for generating a surface acoustic wave, and when an electric signal is applied to one comb-toothed electrode, the piezoelectric film 13 distorts, causing a surface acoustic wave to propagate, and the electric signal is obtained from the other comb-toothed electrode 15a. In the above process, a particular frequency is selected. The frequency band (frequency characteristic) in each surface acoustic wave device has a pass-band characteristic that centers on a frequency (f) calculated by v/d (f=v/d: d is the distance between each tooth of one comb-toothed electrode 15a, and v is the propagation speed of the surface acoustic wave). So, using a hard layer, such as the above-mentioned diamond layer, the propagation speed (v) increases, and consequently, a device capable of generating higher frequencies can be obtained.

A material with insulating properties and good thermal conductivity is suitable for the electrode covering film (electrode covering layer, covering film, first protection film or insulating layer) 18. More specifically, a material with a thermal conductivity better than that of amorphous SiO₂ is suitable. Also, a material with a thermal conductivity equal to or greater than 10 W/mK is suitable.

FIG. 17 shows the thermal conductivity for various types of material. As shown in FIG. 17, zinc oxide, aluminum oxide, and aluminum nitride have a thermal conductivity greater than that of amorphous SiO₂, and also have good insulating properties, so they can be suitable for use in the electrode covering film 18. Also, films made of the above materials show a thermal conductivity equal to or greater than 10 W/mK, and so can be suitable for use in the electrode covering film 18. In particular, zinc oxide and aluminum oxide have piezoelectricity, so can be suitable for use in the electrode covering film 18. In that case, films above and below the electrodes can be the same type of film, and the advantageous effects explained in embodiments 1 and 2 can also be brought about.

The protection film (second protection film, insulating layer, or covering film) 19 is formed on the electrode covering film 18, and is made of an insulating material such as silicon oxide (SiO₂). This protection film 19 functions to protect the piezoelectric film 13 and the comb-toothed electrodes 15a from the ambient environment. The piezoelectric film 13 and the comb-toothed electrodes 15a are covered with the electrode covering film 18, this film 18 also functions as a protection film, but the thickness of the film 18 is small. So the protection film 19 also functions to supplement the protective ability of the film 18. Instead of silicon oxide, alumina (aluminum oxide or AlO₃) or gallium phosphate (GaPO₃) may also be used for the protection film 19.

In particular, when using silicon oxide (SiO₂) for the protection film 19, the film 19 functions to compensate the lower layers (such as ZnO layer and diamond layer) for temperature characteristics. More specifically, the lower layers (such as ZnO layer and diamond layer) have a characteristic of hardening with an increase in temperature, while SiO₂ has a characteristic of softening with an increase in temperature, and with their complementary relationship, frequency change can be reduced.

As explained above, the surface acoustic wave device according to this embodiment has a layered configuration composed of, from top down, the protection film (SiO₂) 19, the electrode covering film 18, the comb-toothed electrodes 15a, the piezoelectric film (ZnO) 13, and the diamond layer 10b.

According to this embodiment, since the comb-toothed electrodes 15a are covered with a material with high thermal conductivity (electrode covering film 18), it is possible to increase heat radiation, and to reduce the deterioration or melting-down of the comb-toothed electrodes 15a. As a result, better electric resistance can be achieved. Furthermore, while maintaining electric resistance, a high phase velocity of 7000 m/s or more can be achieved at the same time.

Although not shown in FIG. 16B, each comb-toothed electrode 15a is coupled with an electrode pad P, and formed as one continuous pattern, for example, as shown in FIG. 3. The electrode covering film 18 and the protection film 19 on the electrode pad P are removed so that the electrode pad P is exposed. The electrode pad P is bonded to an external terminal via a wire or similar (wire bonding), realizing electrical coupling of the surface acoustic wave device with an external device.

Next, the steps in a method for manufacturing the surface acoustic wave device according to this embodiment will be explained.

As shown in FIG. 15A, a diamond substrate with a diamond layer 10b on its main surface is prepared as a substrate 10. For example, a substrate 10 in which a polycrystalline diamond layer 10b of around 15 μm (average thickness) is formed on a silicon layer 10a of around 800 μm (average thickness) is used.

Then, as shown in FIG. 15B, a piezoelectric film 13—for example, a zinc oxide film—is deposited (coated) on the diamond layer 10b, using a film formation method such as an RF spattering method so that the piezoelectric film 13 has a thickness of around 520 nm (average thickness). Film formation is performed, for example, with a power of 0.8 kW, a film-formation temperature of 400° C., and a gas pressure (ambient pressure) of 0.5 Pa, using sintered zinc oxide as a target material, and also using argon (Ar) with a flow rate of 30 sccm and oxygen (O₂) with a flow rate of 30 sccm, as reaction gas.

Next, a conductive film 15, e.g. an Al (aluminum) film is deposited to have a thickness of around 100 nm (average thickness), using a film-formation method such as a DC (direct current) spattering method. Film formation is performed, for example, with a power of 0.9 kW, a film-formation temperature of 25° C. (room temperature), and a gas pressure (ambient pressure) of 0.8 Pa, using Al as a target material, and also using Ar with a flow rate of 40 sccm as ambient gas.

Then, as shown in FIG. 15c, comb-toothed electrodes 15a are formed by patterning the conductive film 15. Patterning is performed in the same way as in embodiment 1.

After that, as shown in FIG. 16A, an electrode covering film 18, e.g. a zinc oxide film is deposited on the exposed portion of the piezoelectric film 13 and on the comb-toothed electrodes 15a, so that it has a thickness of around 30 nm (average thickness) on the piezoelectric film 13. An example of the film-formation method is an RF spattering method, and film-formation is performed, for example, with a power of 0.8 kW, a film-formation temperature of 250° C., and a gas pressure (ambient pressure) of 0.5 Pa, using sintered zinc oxide as a target material, and also using Ar with a flow rate of 30 sccm and O₂ with a flow rate of 30 sccm, as reaction gas. Aluminum oxide or aluminum nitride may also be used for the electrode covering film 18. Films made of those materials are practical, and easily formed.

Next, as shown in FIG. 16B, a protection film (second protection film, insulating layer, or covering film) 19, for example, a silicon oxide film is deposited on the electrode covering film 18 to have a thickness of around 420 nm (average thickness), using a film-formation method, such as an RF spattering method. Film formation is performed, for example, with a power of 0.9 kW, a film-formation temperature of 250° C., and a gas pressure (ambient pressure) of 0.5 Pa, using sintered silicon oxide as a target material, also using Ar with a flow rate of 40 sccm and O₂ with a flow rate of 40 sccm, as reaction gas.

As a result of the steps above, the surface acoustic wave device is almost completed.

According to the above steps, since a material with high thermal conductivity is used for the electrode covering film 18, the device characteristics can be improved. If zinc oxide is used for the electrode covering film 18, the advantageous effects in embodiments 1 and 2 can also be brought about.

Also, according to this embodiment, the advantageous effects in embodiments 1-3 can be obtained even if both piezoelectric film 13 and electrode covering film 18 (in the above-described example, they are both made of zinc oxide) are polycrystalline, which reduces limitations on the lower layer. To be more specific, in order to epitaxially grow monocrystal zinc oxide, the lower diamond layer (hard layer) 10b should be monocrystal. Meanwhile, in this embodiment, even if the lower diamond layer is polycrystal, an excellent device can be achieved. Also, film formation can be performed via, for example, a spattering method, i.e., easy film-formation is realized.

The above embodiments have been described concerning an surface acoustic wave device, but the invention can be widely applied in apparatuses utilizing surface acoustic waves, such as a composite substrate with a piezoelectric body that distorts with the application of voltage, and an electronic apparatus provided with the above device or substrate in combination.

As for applicable electronic apparatuses, the invention is particularly useful when it is applied in communication apparatuses such as cellular phones. For example, the invention can be incorporated in the antenna unit in a cellular phone and functions as a filter for transmission signals.

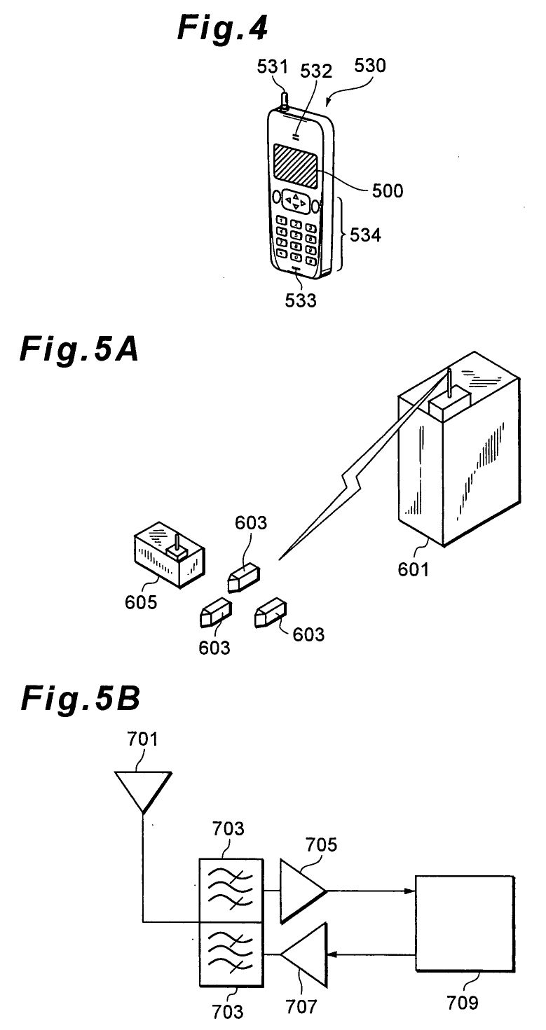

FIG. 4 illustrates an example where the invention is applied in a cellular phone. As shown in FIG. 4, a cellular phone 530 is provided with an antenna unit 531, a voice/audio output unit 532, a voice/audio input unit 533, an operation unit 534, and a display unit 500. The invention can be applied in the antenna unit.

In addition to various electronic apparatuses, the invention can also be used for system apparatuses in broadcasting stations, cellular phone base stations, or similar. In particular, a SAW filter according to the invention can be small (e.g. 1 cm or smaller), and also has good electric resistance, compared to conventional hollow brass resonator filters. So, such a SAW filter can be suitably used for the above system apparatuses. FIG. 5 illustrates an example where the invention is applied in a communication system. As shown in FIG. 5A, in a communication system where signals are transmitted from a base station 601 to individuals and households 603 and an apartment 605, the invention can be applied in an antenna unit in the base station 601. More specifically, as shown in FIG. 5B, a surface acoustic wave device according to the invention can be used for a filter 703 between an antenna unit 701 and a signal processing unit 709. Note that the reference numerals 705 and 707 indicate a low noise amplifier and a high power amplifier, respectively. In particular, stations that function as key stations in a system, regardless of whether it is a wired or wireless system, necessitate a high-performance device (element), so the invention can be suitably applied in those cases. Obviously, the invention may also be applied in each household antenna or in common antenna units in apartments.

The examples and applications explained in the above-described embodiments of the invention may be combined, changed, or improved as required, based on the purpose of use, and the invention is not limited to the above-described embodiments.

What is claimed is:

1. A surface acoustic wave device comprising:
(a) a substrate;
(b) a piezoelectric film formed on top of the substrate;
(c) an electrode for generating a surface acoustic wave formed on top of the piezoelectric film;
(d) a first covering film formed on the electrode to cover the electrode, and made of the same material as that of the piezoelectric film; and
(e) a second covering film formed on the first covering film.

2. The surface acoustic wave device according to claim 1, wherein the piezoelectric film and the first covering film are made of any of zinc oxide, lithium tantalate, lithium niobate, and aluminum nitride.

3. The surface acoustic wave device according to claim 1, wherein the substrate has a hard layer on its surface, and the piezoelectric film is formed on the hard layer.

4. The surface acoustic wave device according to claim 3, wherein the hard layer is made of any of diamond, boron nitride, and sapphire.

5. The surface acoustic wave device according to claim 1, wherein the product kh of the thickness h of the covering film and the wavenumber k of a surface acoustic wave on the surface acoustic wave device is greater than or equal to 0.003 and less than or equal to 0.2.

6. The surface acoustic wave device according to claim 1, wherein the substrate has a polycrystalline hard layer, and the piezoelectric film is formed on the polycrystalline hard layer.

7. A surface acoustic wave device comprising:
(a) a substrate with a hard layer;
(b) a piezoelectric film formed on the hard layer;
(c) an electrode for generating a surface acoustic wave formed on top of the piezoelectric film;
(d) a first covering film formed on the electrode to cover the electrode, and having a thermal conductivity greater than that of amorphous SiO₂; and
(e) a second covering film formed on the first covering film.

8. The surface acoustic wave device according to claim 7, wherein the piezoelectric film is made of any of zinc oxide, lithium tantalate, lithium niobate, and aluminum nitride.

9. The surface acoustic wave device according to claim 7, wherein the first covering film has a thermal conductivity of 10 W/mK or greater.

10. The surface acoustic wave device according to claim 7, wherein the first covering film is zinc oxide or aluminum nitride.

11. The surface acoustic wave device according to claim 7, wherein the product kh of the thickness h of the first covering film and the wavenumber k of a surface acoustic wave on the surface acoustic wave device is greater than 0, but less than or equal to 0.4.

12. An electronic apparatus having the surface acoustic wave device according to claim 1.
